(19) United States
(12) Patent Application Publication
(10) Pub. No.: US 2011/0005823 A1
(43) Pub. Date: Jan. 13, 2011

(54) PRINTED CIRCUIT BOARD HAVING ELECTRO COMPONENT AND MANUFACTURING METHOD THEREOF

(75) Inventors: Sang-Chul LEE, Anyang-si (KR); Yul-Kyo Chung, Yongin-si (KR); Doo-hwan Lee, Euijungboo-si (KR); Sang-Jin Baek, Boeun-gu (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/774,397

(22) Filed: May 5, 2010

(30) Foreign Application Priority Data
Jul. 8, 2009 (KR) 10-2009-0062095

(51) Int. Cl. H05K 1/16; H05K 3/30

(52) U.S. Cl. 174/260; 29/837

(57) ABSTRACT

An electronic component embedded printed circuit board and a manufacturing method thereof are disclosed. In accordance with an embodiment of the present invention, the method includes providing a core board having a circuit pattern formed on a surface thereof, in which the core board is penetrated by a cavity, adhering an adhesive layer to a lower surface of the core board so as to cover the cavity, disposing an electronic component on an upper surface of the adhesive layer, the upper surface corresponding to the cavity, covering the circuit pattern by stacking a first insulator on an upper surface of the core board such that the cavity is filled, the first insulator having no backing material filled therein, and stacking a second insulator on both upper and lower sides of the cord board, in which the second insulator has a backing material filled therein.

### CROSS-REFERENCE TO RELATED APPLICATIONS

This application claims the benefit of Korean Patent Application No. 10-2009-0062095, filed with the Korean Intellectual Property Office on Jul. 8, 2009, the disclosure of which is incorporated herein by reference in its entirety.

### BACKGROUND

1. Technical Field

The present invention relates to an electronic component embedded printed circuit board and a manufacturing method of the printed circuit board.

2. Description of the Related Art

With the development of the electronic industry, there is a growing demand for smaller and higher functional electronic components. Particularly, the trend of the market, based on lighter, thinner, shorter and smaller personal mobile devices, has resulted in thinner printed circuit boards. Emerging as a result are ways of mounting the components that are different from the conventional methods. One example is an embedded printed circuit board, in which an active device such as an IC or a passive device such as an MLCC capacitor is mounted inside the printed circuit board, resulting in a higher density of devices and improved reliability or improved performance of the package itself through a systematic combination of these.

The present invention is contrived to solve problems, such as described below, caused by embedding a thick electronic component during the fabrication of a component-embedded printed circuit board.

In the related art, when an electronic component, for example, a Multi-Layer Ceramic Capacitor (MLCC), with a thickness of 200 um˜1000 um or less is embedded in a core board, an electronic component 30 is embedded by using an adhesive layer 20 in a core board 10 in which a cavity 14 and a circuit 12 are formed, as shown in FIG. 1, and then an insulator 40 made of resin 42 filled with glass fiber 44 is stacked to improve the warpage of the board. In this case, however, the electronic component 30 becomes thicker, and the space around the electronic component and the via holes are not completely filled with the resin 42 of the insulator, as illustrated in FIG. 2. This creates a void 50 in the board and results in poor reliability, requiring improvement.

To solve the above problem, a method of using an insulator 40′ including thick resin 42′ has been suggested, as illustrated in FIG. 3, but this method undesirably increased the overall thickness of the printed circuit board, as illustrated in FIG. 4.

### SUMMARY

The present invention provides an electronic component embedded printed circuit board and a manufacturing method of the printed circuit board that can, even in case a lay-up process is performed by using a thin insulator, prevent a void, caused by degradation of resin content, around an electronic component and between circuit patterns and solve a problem in which the electronic component is deformed by a backing material filled in the insulator during the lay-up process.

An aspect of the present invention provides a manufacturing method of an electronic component embedded printed circuit board that includes providing a core board having a circuit pattern formed on a surface thereof, in which the core board is penetrated by a cavity, adhering an adhesive layer to a lower surface of the core board so as to cover the cavity, disposing an electronic component on an upper surface of the adhesive layer, the upper surface corresponding to the cavity, covering the circuit pattern by stacking a first insulator on an upper surface of the core board such that the cavity is filled, the first insulator having no backing material filled therein, and stacking a second insulator on both upper and lower sides of the cord board, in which the second insulator has a backing material filled therein.

Another aspect of the present invention provides an electronic component embedded printed circuit board that includes a core board, which has an inner layer circuit formed on a surface thereof and in which the core board is penetrated by a cavity, an electronic component, which is embedded in the cavity, a first insulator, which is stacked on an upper surface of the core board so as to fill the cavity and cover the inner layer circuit and in which the first insulator has no backing material filled therein, a second insulator, which is stacked on both upper and lower sides of the core board and in which the second insulator has a backing material filled therein, and a circuit pattern, which is formed on the second insulator.

Here, the first insulator and resin of the second insulator can be made of a same material.

Additional aspects and advantages of the present invention will be set forth in part in the description which follows, and in part will be obvious from the description, or may be learned by practice of the invention.

### BRIEF DESCRIPTION OF THE DRAWINGS

FIGS. 1 to 4 show a method of manufacturing an electronic component embedded printed circuit board in accordance with the related art.

FIG. 5 is a flowchart illustrating a method of manufacturing an electronic component embedded printed circuit board in accordance with an embodiment of the present invention.

FIGS. 6 to 10 show a method of manufacturing an electronic component embedded printed circuit board in accordance with an embodiment of the present invention.

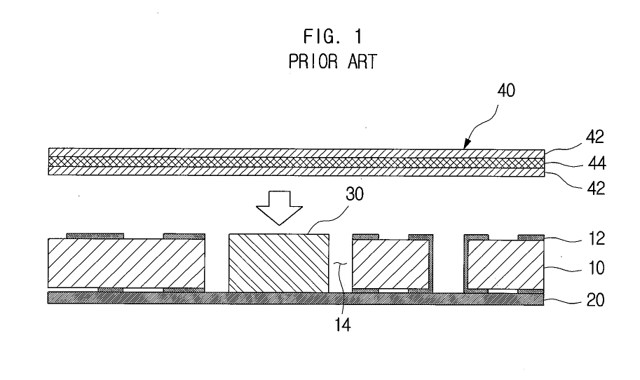

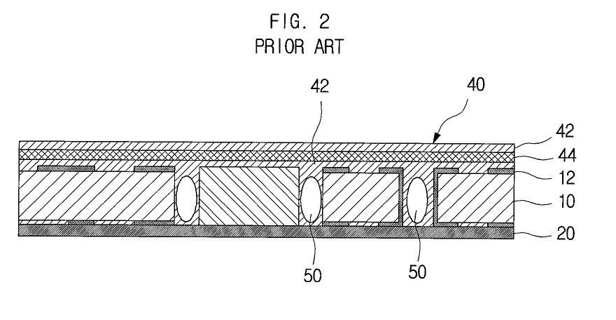

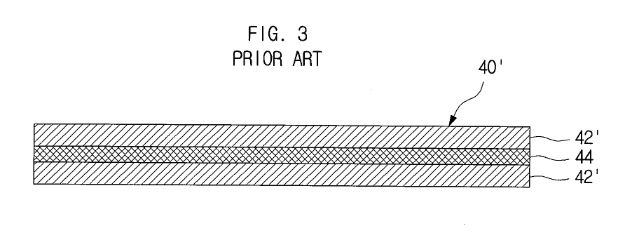

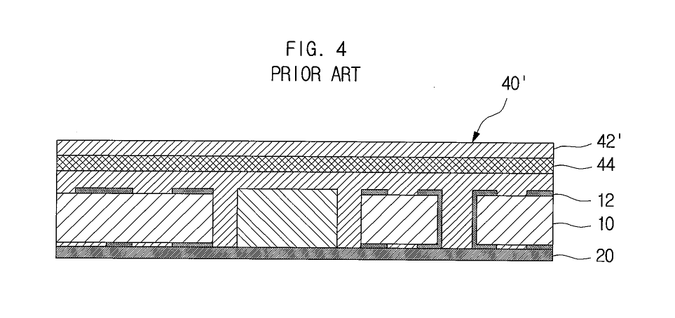

### DETAILED DESCRIPTION

As the invention allows for various changes and numerous embodiments, a particular embodiment will be illustrated in the drawings and described in detail in the written description. However, this is not intended to limit the present invention to a particular mode of practice, and it is to be appreciated that all changes, equivalents, and substitutes that do not depart from the spirit and technical scope of the present invention are encompassed in the present invention.

A method of manufacturing an electronic component embedded printed circuit board according to a certain embodiment of the present invention will be described below in more detail with reference to the accompanying drawings. Those components that are the same or are in correspondence are rendered the same reference numeral regardless of the figure number, and redundant descriptions are omitted.

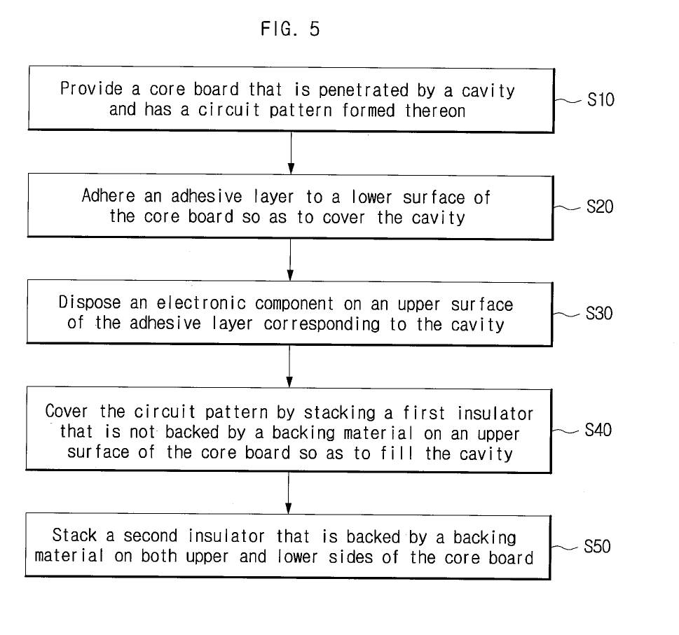

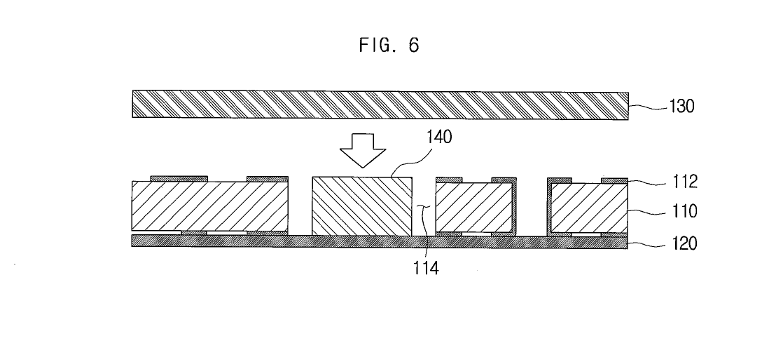

FIG. 5 is a flowchart illustrating a method of manufacturing an electronic component embedded printed circuit board in accordance with an embodiment of the present invention, and FIGS. 6 to 10 show a method of manufacturing an electronic component embedded printed circuit board in accordance with an embodiment of the present invention.

First, as illustrated in FIG. 6, a core board 110, which is penetrated by a cavity 114 and has an inner layer circuit 112 formed thereon, is prepared (S10). Then, an adhesive layer 120 is adhered to a lower surface of the core board 110 so as to cover the cavity 114 (S20). A copper-clad laminate (CCL), for example, can be used as the core board 110, and an epoxy resin in which glass fibers are filled can also be used to reinforce the rigidity. The inner layer circuit 112 is formed on a surface of the core board 110.

In case the copper-clad laminate is used as the core board 110, a seed layer can be formed on both surfaces of the copper-clad laminate by way of electroless plating to form the inner layer circuit 112 on its both surfaces, and then a circuit pattern can be selectively formed by way of electroplating. In another example, the inner layer circuit 112 can be formed by etching a portion of a copper film formed on both surfaces of the copper-clad laminate.

The cavity 114 is formed in a certain portion (for example, a center portion) of the core board 110. The cavity 114 is a space in which an electronic component 140 is embedded and can be formed by using a mechanical drill or a laser drill. A lower side of such processed cavity 114 can be sealed by the adhesive layer 120.

Then, the electronic component 140 is disposed on an upper surface of the adhesive layer 120 corresponding to the cavity 114 (S30, refer to FIG. 6). By disposing the electronic component 140 in this way, the electronic component 140 can be adhered and fixed to an upper surface of the adhesive layer 120 that is exposed through the cavity 114.

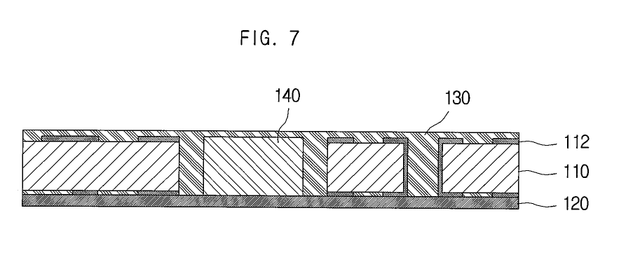

Next, a first insulator 130 that is not backed by a backing material is stacked on an upper surface of the core board 110 so as to fill the cavity 114, and thus the inner layer pattern is covered (S40, refer to FIGS. 6 and 7).

As such, if a flat surface is formed in an upper area of the core board 110 by stacking the first insulator 130 (i.e., primer resin) not backed by a backing material on an upper surface of the core board 110 on which the inner layer circuit 112 is formed, not only can the remaining space of the cavity 114 be filled by the first insulator 130 so that the electronic component 140 can be fixed, but the inside of the via holes can also be filled by the first insulator 130.

The inner layer circuit 112 formed on an upper surface of the core board 110 is also covered by the first insulator 130. Moreover, if the electrodes (not shown) of the electronic component 140 are disposed facing upward (that is, if the electronic component 140 is embedded in a face-up manner), the electrodes (not shown) of the electronic component 140 can also be covered by the resin.

As such, if the first insulator 130 that is not backed by an additional backing material is stacked on the core board 110 before a lay-up process using a second insulator 150 that is backed by a backing material to increase the structural rigidity is performed, all of the remaining space inside the cavity 114, the space inside the via holes, the space between the circuit patterns 112 and the space between the circuit patterns and the electrodes of the electronic component 140 can be filled. Therefore, even in case the thin second insulator 150 having a small resin content is stacked in a following process, this allows no void to be formed in the cavity 114, the via holes, the space between the circuit patterns 112 and the space between the circuit patterns 112 and the electrodes (not shown) of the electronic component 140.

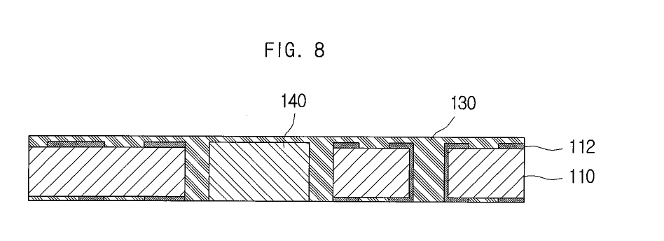

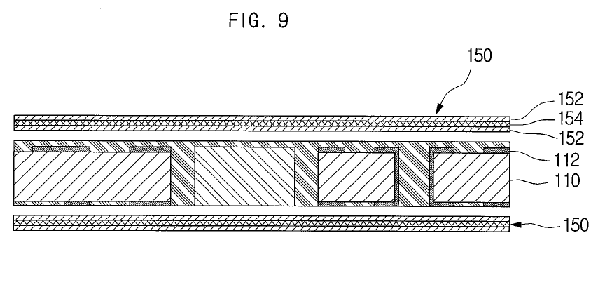

Next, the adhesive layer 120 is removed (S50, refer to FIG. 8), and then the second insulator 150 backed by a backing material 154 is stacked on both upper and lower sides of the core board 110 (S60, refer to FIG. 9). Here, resin 152 of the second insulator 150 can be made of the same material as that of the first insulator 130. That is, the second insulator 150 that includes the same material as that of the first insulator 130 used to fill the cavity 114 and the via holes can be used. By using such insulators of the same material, there is less chance of warpage, which is caused by the difference in the coefficients of thermal expansion between the surfaces of the first insulator 130 and the second insulator 150, thus providing adequate adhesion between the first insulator 130 and the second insulator 150. This solves problems caused by delamination between layers.

Furthermore, since all voids inside the cavity 114, inside the via holes and between the circuit patterns 112 are filled by the first insulator 130, the thin second insulator 150 having a small resin content can be used without a possibility of the voids, resulting in a thinner printed circuit board. Moreover, the first insulator 130 can perform a function of buffering between the backing material 154 filled in the second insulator 150 and the electrodes of the electronic component 140 and/or the circuit patterns 112. This can solve a problem in which the electronic component 140 and/or the circuit patterns 112 may be deformed while the backing material 154 inside the second insulator 150 is in contact with the electrodes (not shown) of the electronic component 140 and/or the circuit patterns 112.

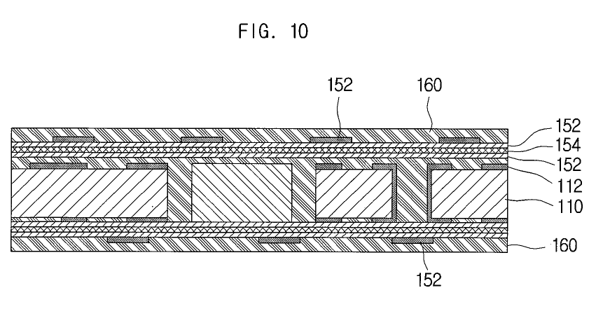

Then, another circuit pattern 162 is formed on an upper surface of the second insulator 150 (refer to FIG. 10). The circuit pattern 162 formed on the upper surface of the second insulator 150 can be protected by a solder resist 160, as illustrated in FIG. 10. Of course, if a printed circuit board with more layers is to be manufactured, an additional lay-up process can be performed without forming the solder resist 160.

Illustrated in FIG. 10 is a printed circuit board that is manufactured through such processes described above. In a printed circuit board according to an embodiment of the present invention, the electronic component 140 is mounted inside the cavity 114 formed in the core board 110, and then the cavity 114 is filled by stacking the first insulator 130, which is not backed by a backing material, on its upper surface. The first insulator 130 also covers the inner layer circuit 112. Then, the second insulator 150, which is backed by the backing material 154, is stacked on both the upper and lower sides of the core board 110 on which the first insulator 130 is stacked, and then the circuit pattern 162 is formed on the second insulator 150.

As described above, since the first insulator 130 and the resin 152 of the second insulator 150 are made of the same material, there is a less chance of warpage, which is caused by the difference in the coefficients of thermal expansion between the surfaces of the first insulator 130 and the second insulator 150, thus providing adequate adhesion between the first insulator 130 and the second insulator 150.

While the spirit of the present invention has been described in detail with reference to a particular embodiment, the embodiments are for illustrative purposes only and shall not limit the present invention. It is to be appreciated that those skilled in the art can change or modify the embodiment without departing from the scope and spirit of the present invention.

As such, many embodiments other than that set forth above can be found in the appended claims.

What is claimed is:

1. A method of manufacturing an electronic component embedded printed circuit board, the method comprising:
providing a core board having a circuit pattern formed on a surface thereof, the core board being penetrated by a cavity;
adhering an adhesive layer to a lower surface of the core board so as to cover the cavity;
disposing an electronic component on an upper surface of the adhesive layer, the upper surface corresponding to the cavity;
covering the circuit pattern by stacking a first insulator on an upper surface of the core board such that the cavity is filled, the first insulator having no backing material filled therein; and
stacking a second insulator on both upper and lower sides of the cord board, the second insulator having a backing material filled therein.

2. The method of claim 1, wherein the first insulator and resin of the second insulator are made of a same material.

3. An electronic component embedded printed circuit board comprising:
a core board having an inner layer circuit formed on a surface thereof, the core board being penetrated by a cavity;
an electronic component embedded in the cavity;
a first insulator stacked on an upper surface of the core board so as to fill the cavity and cover the inner layer circuit, the first insulator having no backing material filled therein;
a second insulator stacked on both upper and lower sides of the core board, the second insulator having a backing material filled therein; and
a circuit pattern formed on the second insulator.

4. The electronic component embedded printed circuit board of claim 3, wherein the first insulator and resin of the second insulator are made of a same material.
